(19) United States
(12) Patent Application Publication
(10) Pub. No.: US 2025/0191993 A1
(43) Pub. Date: Jun. 12, 2025

(54) SEMICONDUCTOR DEVICE ASSEMBLY WITH THERMALLY-CONDUCTIVE FILLER IN AN INTER-DIE GAP

(71) Applicant: Micron Technology, Inc., Boise, ID (US)

(72) Inventors: Chesheng KUNG, Taichung City (TW); Chien Hao HSU, Taichung City (TW); Hung Wen LIU, Taichung City (TW); Vladimir NOVESKI, San Diego, CA (US); Jin Yuan LAI, Taichung City (TW)

(21) Appl. No.: 18/966,922

(22) Filed: Dec. 3, 2024

Related U.S. Application Data
(60) Provisional application No. 63/607,322, filed on Dec. 7, 2023.

(51) Int. Cl. H01L 23/367; H01L 23/00; H01L 23/31; H01L 23/373; H01L 25/00; H01L 25/18; H10B 80/00

(52) U.S. Cl. CPC H01L 23/3675; H01L 23/3135; H01L 23/3736; H01L 24/26; H01L 24/27; H01L 24/32; H01L 25/18; H01L 25/50; H01L 24/48; H01L 2224/26175; H01L 2224/27013; H01L 2224/27515; H01L 2224/32137; H01L 2224/48227; H01L 2225/1023; H01L 2225/1041; H01L 2225/1058; H01L 2225/1094; H01L 2924/1431; H10B 80/00

(57) ABSTRACT

Implementations described herein relate to various semiconductor device assemblies. In some implementations, a semiconductor device assembly includes a substrate, a first semiconductor die disposed on the substrate, and a second semiconductor die disposed on the substrate spaced from the first semiconductor die to define a gap between the first semiconductor die and the second semiconductor die. The semiconductor device assembly may include a thermally-conductive filler disposed in the gap between the first semiconductor die and the second semiconductor die.

### CROSS REFERENCE TO RELATED APPLICATION

This Patent Application claims priority to U.S. Provisional Patent Application No. 63/607,322, filed on Dec. 7, 2023, and entitled “SEMICONDUCTOR DEVICE ASSEMBLY WITH THERMALLY-CONDUCTIVE FILLER IN AN INTER-DIE GAP.” The disclosure of the prior Application is considered part of and is incorporated by reference into this Patent Application.

### TECHNICAL FIELD

The present disclosure generally relates to semiconductor devices and methods of forming semiconductor devices. For example, the present disclosure relates to a semiconductor device assembly with a thermally-conductive filler in an inter-die gap.

### BACKGROUND

A semiconductor package may include a semiconductor substrate, one or more semiconductor electronic components coupled to and/or embedded in the semiconductor substrate, and a casing formed over the semiconductor substrate to encapsulate the one or more semiconductor electronic components. The one or more semiconductor electronic components may be interconnected by electrical interconnects to form one or more semiconductor devices, such as one or more integrated circuits (ICs) (e.g., one or more dies or chips). For example, the semiconductor electronic components and the electrical interconnects may be fabricated on a semiconductor wafer to form one or more ICs before being diced into dies or chips and then packaged. A semiconductor package may be referred to as a semiconductor chip package that includes one or more ICs. A semiconductor package protects the semiconductor electronic components and the electrical interconnects from damage and includes a mechanism for connecting the semiconductor electronic components and the electrical interconnects to external components (e.g., a circuit substrate), such as via balls, pins, leads, contact pads, or other electrical interconnect structures. A semiconductor device assembly may be or may include a semiconductor package, multiple semiconductor packages, and/or one or more components of a semiconductor package (e.g., one or more semiconductor devices with or without a casing).

An electronic system assembly may include multiple semiconductor packages electrically coupled to a carrier substrate (e.g., circuit substrate). An electronic system assembly may include additional system components electrically coupled to the carrier substrate. The carrier substrate may include electrical interconnects and conductive paths used for interconnecting system components, including the multiple semiconductor packages and other system components of the electronic system assembly. Accordingly, the multiple semiconductor packages may be electrically connected to each other and/or to one or more additional system components via the carrier substrate to form the electronic system assembly. By way of example, other system components may include passive components (e.g., storage capacitors), processing units (e.g., a central processing unit (CPU), a graphics processing unit (GPU), a microprocessor, and/or a microcontroller), control units (e.g., a microcontroller, a memory controller, and/or a power management controller), or one or more other electronic components.

### BRIEF DESCRIPTION OF THE DRAWINGS

FIG. 1 is a diagram of an example apparatus that may be manufactured using techniques described herein.

FIG. 2 is a diagram of an example memory device that may be manufactured using techniques described herein.

FIG. 3 is a diagram showing a sectional view of an example apparatus.

FIG. 4 is a diagram showing a perspective view of an example semiconductor package.

FIG. 5 is a diagram of an example of a semiconductor package.

FIGS. 6A-6B are diagrams of an example of a semiconductor package.

FIGS. 7A-7B are diagrams of an example of a semiconductor package.

FIG. 8 is a flowchart of an example method of forming an integrated assembly or memory device having a thermally-conductive filler in an inter-die gap.

FIG. 9 is a flowchart of an example method of forming an integrated assembly or memory device having a thermally-conductive filler in an inter-die gap.

### DETAILED DESCRIPTION

Semiconductor devices have become more powerful and compact, leading to the need for effective heat dissipation strategies. Inadequate heat dissipation can result in a reduced useful life and/or affect a performance of a semiconductor device. In one example, a logic package, such as a system on a chip (SoC), may experience thermal issues due to having a high power density and limited space for heat dissipation. For example, the logic package may be part of a package-on-package (PoP) assembly, in which a memory package is stacked on top of the logic package. While this configuration facilitates higher component density, the logic package may experience high temperatures due to the tight arrangement and insufficient heat dissipation.

Some implementations described herein enable improved heat dissipation in a semiconductor package. A semiconductor package may include multiple dies or die stacks in a side-by-side arrangement thereby defining a gap between the dies or die stacks (i.e., an inter-die gap). In some implementations, the gap may be filled with a thermally-conductive filler, such as a thermal paste. The thermally-conductive filler may reduce thermal resistance in the semiconductor package, thereby improving the thermal properties of the semiconductor package.

The semiconductor package may be stacked on one or more other packages in a PoP assembly. For example, the semiconductor package (e.g., a memory package) may be stacked on a logic package, such as an SoC, in a PoP assembly. In this arrangement, the thermally-conductive filler of the semiconductor package enables improved dispersion of heat from the logic package through the dies of the semiconductor package by reducing thermal resistance from the logic package to the dies. Accordingly, the logic package may experience thermal improvement (e.g., by 2° Celsius or more). Moreover, the heat dispersion through the dies of the semiconductor package may have little thermal impact on the dies themselves.

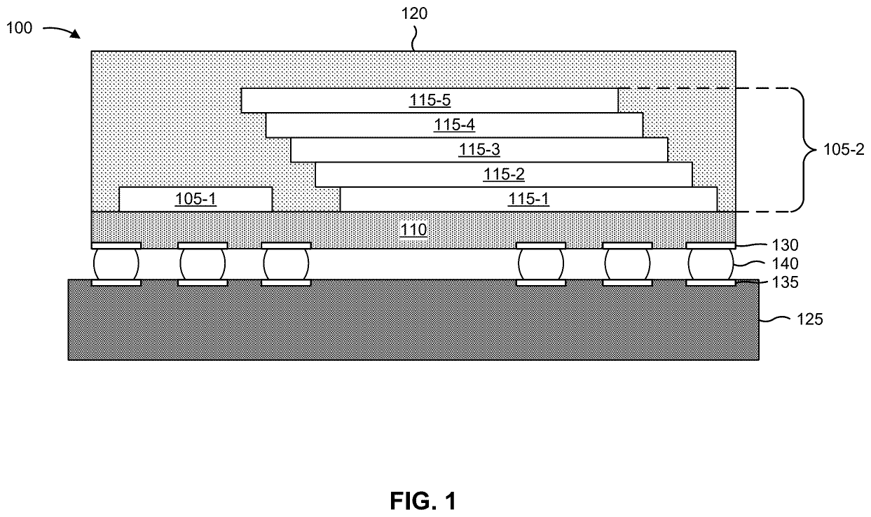

FIG. 1 is a diagram of an example apparatus 100 that may be manufactured using techniques described herein. The apparatus 100 may include any type of device or system that includes one or more integrated circuits 105. For example, the apparatus 100 may include a memory device, a flash memory device, a NAND memory device, a NOR memory device, a random access memory (RAM) device, a read-only memory (ROM) device, a dynamic RAM (DRAM) device, a static RAM (SRAM) device, a solid state drive (SSD), a microchip, and/or a system on a chip (SoC), among other examples. In some cases, the apparatus 100 may be referred to as a semiconductor package, an assembly, a semiconductor device assembly, or an integrated assembly.

As shown in FIG. 1, the apparatus 100 may include one or more integrated circuits 105, shown as a first integrated circuit 105-1 and a second integrated circuit 105-2, disposed on a substrate 110. An integrated circuit 105 may include any type of circuit, such as an analog circuit, a digital circuit, a radiofrequency (RF) circuit, a power supply, a power management circuit, an input-output (I/O) chip, an application-specific integrated circuit (ASIC), a field-programmable gate array (FPGA), and/or a memory device (e.g., a NAND memory device, a NOR memory device, a RAM device, or a ROM device). An integrated circuit 105 may be mounted on or otherwise disposed on a surface of the substrate 110. Although the apparatus 100 is shown as including two integrated circuits 105 as an example, the apparatus 100 may include a different number of integrated circuits 105.

In some implementations, an integrated circuit 105 may include a single semiconductor die 115 (sometimes called a die), as shown by the first integrated circuit 105-1. In some implementations, an integrated circuit 105 may include multiple semiconductor dies 115 (sometimes called dies), as shown by the second integrated circuit 105-2, which is shown as including five semiconductor dies 115-1 through 115-5.

As shown in FIG. 1, for an integrated circuit 105 that includes multiple dies 115, the dies 115 may be stacked on top of each other to reduce a footprint of the apparatus 100. In some implementations, a spacer may be present between dies 115 that are adjacent to one another in the stack to enable electrical separation and heat dissipation. The stacked dies 115 may include three-dimensional electrical interconnects, such as through-silicon vias (TSVs), to route electrical signals between dies 115. Although the integrated circuit 105-2 is shown as including five dies 115, an integrated circuit 105 may include a different number of dies 115 (e.g., at least two dies 115). A first die 115-1 (sometimes called a bottom die or a base die) may be disposed on the substrate 110, a second die 115-2 may be disposed on the first die 115-1, and so on. Although FIG. 1 shows the dies 115 stacked in a shingle stack (e.g., with die edges that are not aligned, which provides space for wire bonding near the edges of the dies 115), in some implementations, the dies 115 may be stacked in a different arrangement, such as a straight stack (e.g., with aligned die edges).

The apparatus 100 may include a casing 120 that protects internal components of the apparatus 100 (e.g., the integrated circuits 105) from damage and environmental elements (e.g., particles) that can lead to malfunction of the apparatus 100. The casing 120 may be a mold compound, a plastic (e.g., an epoxy plastic), a ceramic, or another type of material depending on the functional requirements for the apparatus 100.

In some implementations, the apparatus 100 may be included as part of a higher-level system (e.g., a computer, a mobile phone, a network device, an SSD, a vehicle, or an Internet of Things device), such as by electrically connecting the apparatus 100 to a circuit board 125, such as a printed circuit board. For example, the substrate 110 may be disposed on the circuit board 125 such that electrical contacts 130 (e.g., bond pads) of the substrate 110 are electrically connected to electrical contacts 135 (e.g., bond pads) of the circuit board 125.

In some implementations, the substrate 110 may be mounted on the circuit board 125 using solder balls 140 (e.g., arranged in a ball grid array), which may be melted to form a physical and electrical connection between the substrate 110 and the circuit board 125. Additionally, or alternatively, the substrate 110 may be mounted on and/or electrically connected to the circuit board 125 using another type of connector, such as pins or leads. Similarly, an integrated circuit 105 may include electrical pads (e.g., bond pads) that are electrically connected to corresponding electrical pads (e.g., bond pads) of the substrate 110 using electrical bonding, such as wire bonding, bump bonding, or the like. The interconnections between an integrated circuit 105, the substrate 110, and the circuit board 125 enable the integrated circuit 105 to receive and transmit signals to other components of the apparatus 100 and/or the higher-level system.

As indicated above, FIG. 1 is provided as an example. Other examples may differ from what is described with regard to FIG. 1.

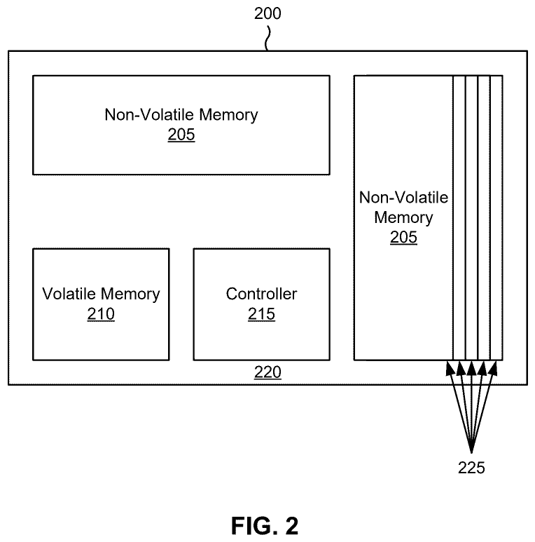

FIG. 2 is a diagram of an example memory device 200 that may be manufactured using techniques described herein. The memory device 200 is an example of the apparatus 100 described above in connection with FIG. 1. The memory device 200 may be any electronic device configured to store data in memory. In some implementations, the memory device 200 may be an electronic device configured to store data persistently in non-volatile memory 205. For example, the memory device 200 may be a hard drive, an SSD, a flash memory device (e.g., a NAND flash memory device or a NOR flash memory device), a universal serial bus (USB) thumb drive, a memory card (e.g., a secure digital (SD) card), a secondary storage device, a non-volatile memory express (NVMe) device, and/or an embedded multimedia card (eMMC) device.

As shown, the memory device 200 may include non-volatile memory 205, volatile memory 210, and a controller 215. The components of the memory device 200 may be mounted on or otherwise disposed on a substrate 220. In some implementations, the non-volatile memory 205 includes a single die. Additionally, or alternatively, the non-volatile memory 205 may include multiple dies, such as stacked semiconductor dies 225 (e.g., in a straight stack, a shingle stack, or another type of stack), as described above in connection with FIG. 1.

The non-volatile memory 205 may be configured to maintain stored data after the memory device 200 is powered off. For example, the non-volatile memory 205 may include NAND memory or NOR memory. The volatile memory 210 may require power to maintain stored data and may lose stored data after the memory device 200 is powered off. For example, the volatile memory 210 may include one or more latches and/or RAM, such as DRAM and/or SRAM. As an example, the volatile memory 210 may cache data read from or to be written to non-volatile memory 205, and/or may cache instructions to be executed by the controller 215.

The controller 215 may be any device configured to communicate with the non-volatile memory 205, the volatile memory 210, and a host device (e.g., via a host interface of the memory device 200). For example, the controller 215 may include a memory controller, a system controller, an ASIC, an FPGA, a processor, a microcontroller, and/or one or more processing components. In some implementations, the memory device 200 may be included in a system that includes the host device. The host device may include one or more processors configured to execute instructions and store data in the non-volatile memory 205.

The controller 215 may be configured to control operations of the memory device 200, such as by executing one or more instructions (sometimes called commands). For example, the memory device 200 may store one or more instructions as firmware, and the controller 215 may execute those one or more instructions. Additionally, or alternatively, the controller 215 may receive one or more instructions from a host device via a host interface, and may execute those one or more instructions. For example, the controller 215 may transmit signals to and/or receive signals from the non-volatile memory 205 and/or the volatile memory 210 based on the one or more instructions, such as to transfer data to (e.g., write or program), to transfer data from (e.g., read), and/or to erase all or a portion of the non-volatile memory 205 (e.g., one or more memory cells, pages, sub-blocks, blocks, or planes of the non-volatile memory 205).

As indicated above, FIG. 2 is provided as an example. Other examples may differ from what is described with regard to FIG. 2. The number and arrangement of components shown in FIG. 2 are provided as an example. In practice, there may be additional components, fewer components, different components, or differently arranged components than those shown in FIG. 2.

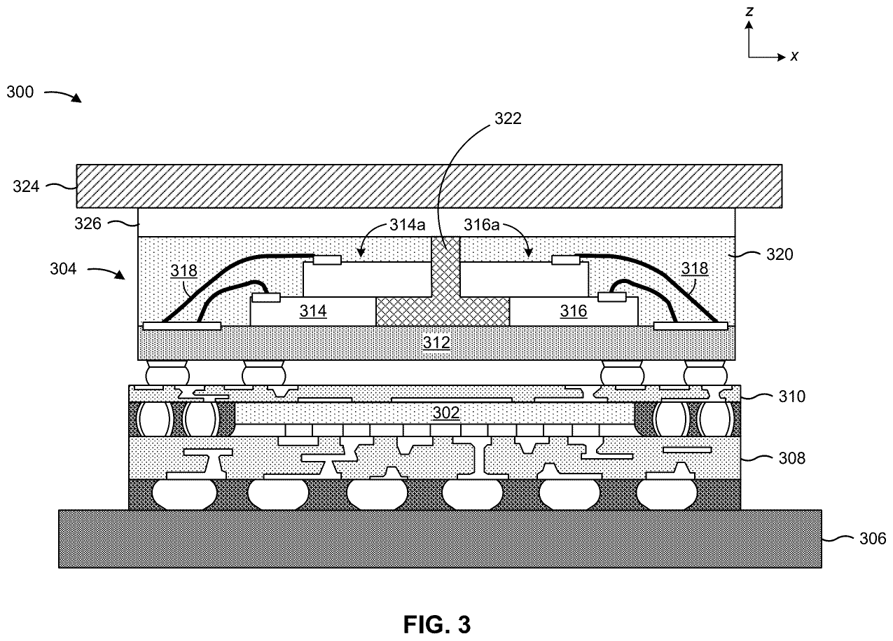

FIG. 3 is a diagram showing a sectional view of an example apparatus 300. The apparatus 300 may include a semiconductor package 302 (i.e., a first semiconductor package) and a semiconductor package 304 (i.e., a second semiconductor package) in a PoP configuration. For example, the semiconductor package 304 may be stacked on the semiconductor package 302. In some implementations, the semiconductor package 302 may be a logic package and the semiconductor package 304 may be a memory package. For example, the semiconductor package 302 may be an SoC or may include an SoC.

The apparatus 300 may include a substrate 306, such as a circuit board (e.g., a printed circuit board), a redistribution layer, or the like. The semiconductor package 302 and the semiconductor package 304 may be disposed on (e.g., connected to) the substrate 306. The semiconductor package 304, or components thereof, may correspond to the apparatus 100 or components thereof. In some implementations, the apparatus 300 may include a first redistribution layer 308 between the substrate 306 and the semiconductor package 302. In some implementations, the apparatus 300 may include a second redistribution layer 310 between the semiconductor package 302 and the semiconductor package 304. In some implementations, interconnections between the first redistribution layer 308 and the substrate 306, and/or between the semiconductor package 304 and the second redistribution layer 310, may be made via solder balls. In some implementations, interconnections between the semiconductor package 302 and the first redistribution layer 308 may be made via interconnects, such as pillars.

As shown, the semiconductor package 304 may include a substrate 312, a first semiconductor die 314 disposed on the substrate 312, and a second semiconductor die 316 disposed on the substrate 312. The substrate 312 may include a semiconductor substrate, a redistribution layer, or the like. In some implementations, the first semiconductor die 314 may be included in a first semiconductor die stack 314a (e.g., that includes a plurality of semiconductor dies) and the second semiconductor die 316 may be included in a second semiconductor die stack 316a (e.g., that includes a plurality of semiconductor dies), as shown. The first semiconductor die 314 and the second semiconductor die 316 may be spaced apart to define a gap between the first semiconductor die 314 and the second semiconductor die 316 (e.g., the gap may be between the first semiconductor die stack 314a and the second semiconductor die stack 316a). The gap may be a channel, or similar feature, extending along edges of the first semiconductor die 314 and the second semiconductor die 316 that face each other (e.g., edges of the first semiconductor die stack 314a and the second semiconductor die stack 316a that face each other). The first semiconductor die 314 and the second semiconductor die 316 may be memory dies (e.g., the first semiconductor die stack 314a and the second semiconductor die stack 316a may each include a plurality of memory dies).

The first semiconductor die 314 and the second semiconductor die 316 may be electrically connected to the substrate 312 (e.g., to bond pads of the substrate 312) by wire bonds 318. For example, the first semiconductor die stack 314a and the second semiconductor die stack 316a may have shingle stack configurations, and semiconductor dies of the first semiconductor die stack 314a and the second semiconductor die stack 316a may be wire bonded to the substrate. As an example, the wire bonds 318 may be along outward-facing edges (e.g., edges that do not face the gap) of the semiconductor dies of the first semiconductor die stack 314a and the second semiconductor die stack 316a, and edges of the semiconductor dies of the first semiconductor die stack 314a and the second semiconductor die stack 316a that face the gap may be free of wire bonds. In other words, the semiconductor dies of the first semiconductor die stack 314a and the second semiconductor die stack 316a may be shingled to expose outward-facing edges of the semiconductor dies for wire bonding. In some implementations, the first semiconductor die stack 314a and/or the second semiconductor die stack 316a may have straight stack configurations.

The semiconductor package 304 may include a casing 320 encapsulating the first semiconductor die 314 and the second semiconductor die 316. For example, the casing 320 may encapsulate the first semiconductor die stack 314a and the second semiconductor die stack 316a. The casing 320 may also encapsulate the wire bonds 318. In some implementations, the casing 320 may include a mold compound.

A thermally-conductive filler 322 may be disposed in (e.g., may fill) the gap between the first semiconductor die 314 and the second semiconductor die 316. For example, the thermally-conductive filler 322 may be disposed in (e.g., may fill) the gap between the first semiconductor die stack 314a and the second semiconductor die stack 316a. The thermally-conductive filler 322 may be dispensed, injected, pressed, or the like, into the gap. For example, the thermally-conductive filler 322 may be spirally dispensed into the gap (e.g., dispensed over the first semiconductor die 314 and the second semiconductor die 316, or the first semiconductor die stack 314a and the second semiconductor die stack 316a, in a spiraling manner so that the thermally-conductive filler 322, in an un-cured state, flows into the gap).

The thermally-conductive filler 322 may facilitate thermal dispersion from the semiconductor package 302 through the semiconductor package 304 (e.g., through the semiconductor dies of the semiconductor package 304).

In some implementations, the thermally-conductive filler 322 may include a flowable material (e.g., a liquid) that hardens by curing. In some implementations, the thermally-conductive filler 322 may have a viscosity that is sufficiently low, before curing, to enable the thermally-conductive filler 322 to fill the gap without forming voids (e.g., because the gap may have an irregular shape). In some implementations, the thermally-conductive filler 322 may include a deformable material (e.g., that hardens by curing or that remains deformable) that is suitable for packing into the gap.

The thermally-conductive filler 322 may include a carrier (e.g., a silicone carrier, an epoxy carrier, or the like) doped with particles of a thermally-conductive material (e.g., metal particles). As examples, the thermally-conductive filler 322 may include a thermally-conductive paste (also referred to as “thermal paste”), a thermally-conductive adhesive (also referred to as “thermal adhesive”), a thermally-conductive grease (also referred to as “thermal grease”), a thermally-conductive gel (also referred to as a “thermal gel”), a thermally-conductive putty (also referred to as “thermal putty”), a conductive ink, a metal-based material (e.g., a metal-based thermal interface material), a carbon-based material (e.g., a carbon-based thermal interface material), or any combination thereof.

The thermally-conductive filler 322 may have a higher thermal conductivity than a thermal conductivity of the casing 320. The casing 320 may have a thermal conductivity of approximately 5 watts per meter-kelvin (W/m·K) or less (e.g., 3 W/m·K). For example, the casing 320 may have a thermal conductivity of approximately 0.8 W/m·K. In some implementations, the thermally-conductive filler 322 may have a thermal conductivity greater than approximately 3 W/m·K. For example, the thermally-conductive filler 322 may have a thermal conductivity of at least 10 W/m·K. In some implementations, the thermally-conductive filler 322 may have a thermal conductivity in a range from 10 to 250 W/m·K, such as a thermal conductivity of 10 W/m·K, 20 W/m·K, 30 W/m·K, 40 W/m·K, 50 W/m·K, 60 W/m·K, or 70 W/m·K, among other examples. Such thermal conductivities may produce heat dissipation that is comparable to using a casing 320 with a high thermal conductivity.

The thermally-conductive filler 322 may be filled in the gap up to a level that is short of the tops of the first semiconductor die 314 and the second semiconductor die 316, if die stacking is not used, or short of the tops of the first semiconductor die stack 314a and the second semiconductor die stack 316a. Alternatively, the thermally-conductive filler 322 may be filled in the gap flush to the tops of the first semiconductor die 314 and the second semiconductor die 316, if die stacking is not used, or flush to the tops of the first semiconductor die stack 314a and the second semiconductor die stack 316a. Alternatively, the thermally-conductive filler 322 may extend from the gap beyond the tops of the first semiconductor die 314 and the second semiconductor die 316, if die stacking is not used, or beyond the tops of the first semiconductor die stack 314a and the second semiconductor die stack 316a (as shown). For example, the thermally-conductive filler 322 may extend from the gap onto top surfaces of the first semiconductor die 314 and the second semiconductor die 316, if die stacking is not used, or onto top surfaces of the first semiconductor die stack 314a and the second semiconductor die stack 316a.

In some implementations, each end of the gap may be blocked by a respective dam (not shown), and the thermally-conductive filler 322 may be disposed in the gap between the dams. For example, a first dam may be disposed in the gap (e.g., blocking a first end of the gap) and a second dam may be disposed in the gap (e.g., blocking a second end of the gap), and the thermally-conductive filler 322 may be disposed in the gap between the first dam and the second dam. A dam may include a bead of epoxy, or another type of obstruction that is resistant to the thermally-conductive filler 322, in a non-cured state (e.g., a liquid state), leaking from the gap.

In some implementations, the top-most elements of the first semiconductor die stack 314a and the second semiconductor die stack 316a are dummy dies or spacers. For example, the first semiconductor die stack 314a may include one or more active semiconductor dies (e.g., the first semiconductor die 314) and a dummy die (e.g., a nonactive semiconductor die) or a spacer on top of the one or more active semiconductor dies. Similarly, the second semiconductor die stack 316a may include one or more active semiconductor dies (e.g., the second semiconductor die 316) and a dummy die or a spacer on top of the one or more active semiconductor dies. A dummy die or a spacer may provide protection against the thermally-conductive filler 322 interfering with electrical signals of active semiconductor dies.

The apparatus 300 may include a heat spreader 324 disposed on the semiconductor package 304. The heat spreader 324 is a thermally-conductive body (e.g., a plate, a sheet, a block, or the like) that may be formed from a metal or another thermally-conductive material (e.g., copper, aluminum, alloys thereof, graphite, thermally-conductive polymers, or the like). A thermal interface material layer 326 may be disposed between the heat spreader 324 and a top surface of the semiconductor package 304. The thermal interface material layer 326 may include a thermal interface material, such as a thermal paste, a thermal adhesive, a thermal grease, a thermal gel, a thermal putty, or the like.

In some implementations, the thermally-conductive filler 322 may contact the heat spreader 324 and/or the thermal interface material layer 326. This may be possible when the thermally-conductive filler 322 extends from the gap beyond the tops of the first semiconductor die 314 and the second semiconductor die 316 (or beyond the tops of the first semiconductor die stack 314a and the second semiconductor die stack 316a). For example, the casing 320 may be back-grinded to expose the thermally-conductive filler 322 to facilitate contact between the thermally-conductive filler 322 and the heat spreader 324 and/or the thermal interface material layer 326.

As indicated above, FIG. 3 is provided as an example. Other examples may differ from what is described with respect to FIG. 3.

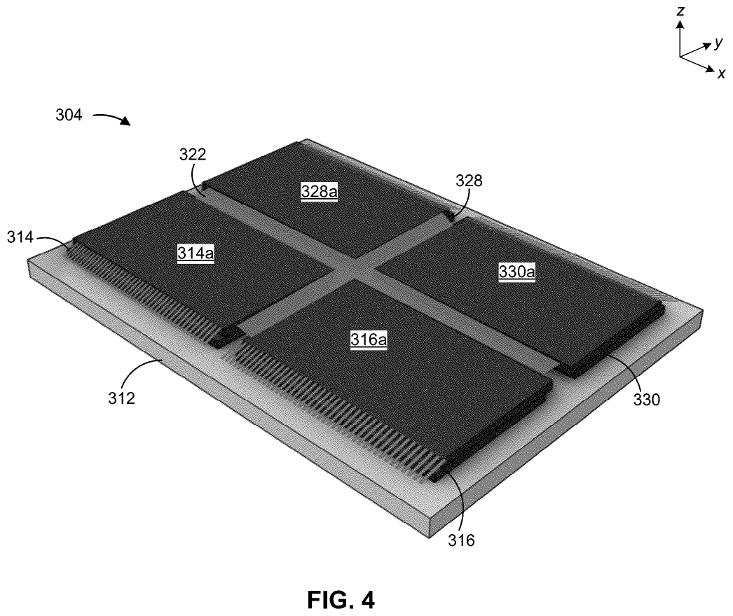

FIG. 4 is a diagram showing a perspective view of an example of the semiconductor package 304. The semiconductor package 304 is shown in FIG. 4 without the casing 320 for illustration purposes.

As shown, the semiconductor package 304 may include the first semiconductor die 314, the second semiconductor die 316, a third semiconductor die 328, and a fourth semiconductor die 330 disposed on the substrate 312. For example, the semiconductor package 304 may include the first semiconductor die stack 314a, the second semiconductor die stack 316a, a third semiconductor die stack 328a (including the third semiconductor die 328), and a fourth semiconductor die stack 330a (including the fourth semiconductor die 330) disposed on the substrate 312. The semiconductor package 304 may include multiple single-die towers or multiple die stacks in any quantity, such as 2, 4 (as shown), 6, or 8. When more than two semiconductor dies or semiconductor die stacks are disposed on the substrate 312, the gap between semiconductor dies or semiconductor die stacks may include multiple intersecting channels (e.g., linear channels). For example, as shown, the gap may be a cross-shaped gap.

As indicated above, FIG. 4 is provided as an example. Other examples may differ from what is described with respect to FIG. 4.

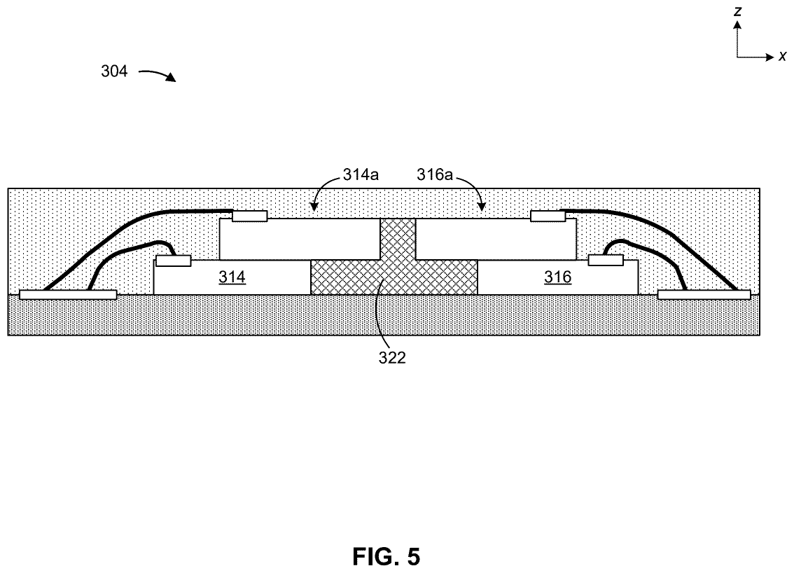

FIG. 5 is a diagram of an example of the semiconductor package 304. As shown in FIG. 5, the thermally-conductive filler 322 may be filled in the gap flush to the tops of the first semiconductor die stack 314a and the second semiconductor die stack 316a, as described herein. If die stacking is not used, the thermally-conductive filler 322 may be filled in the gap flush to the tops of the first semiconductor die 314 and the second semiconductor die 316.

As indicated above, FIG. 5 is provided as an example. Other examples may differ from what is described with respect to FIG. 5.

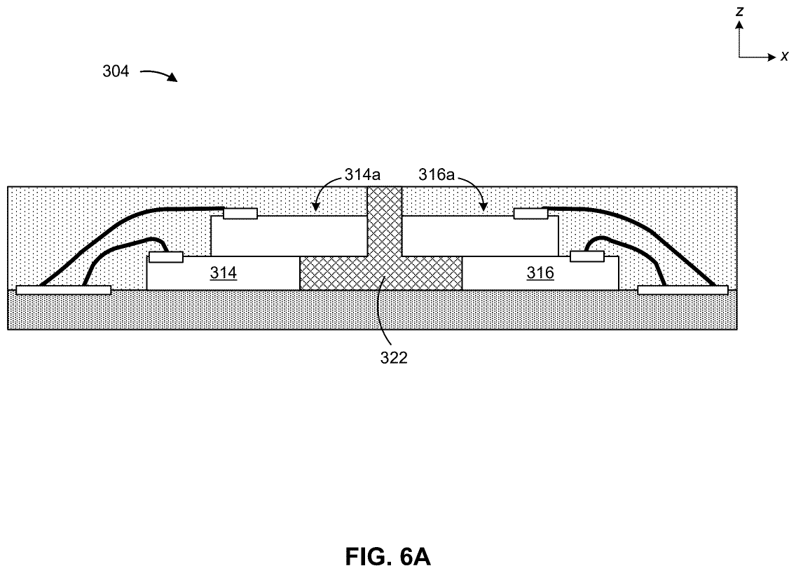

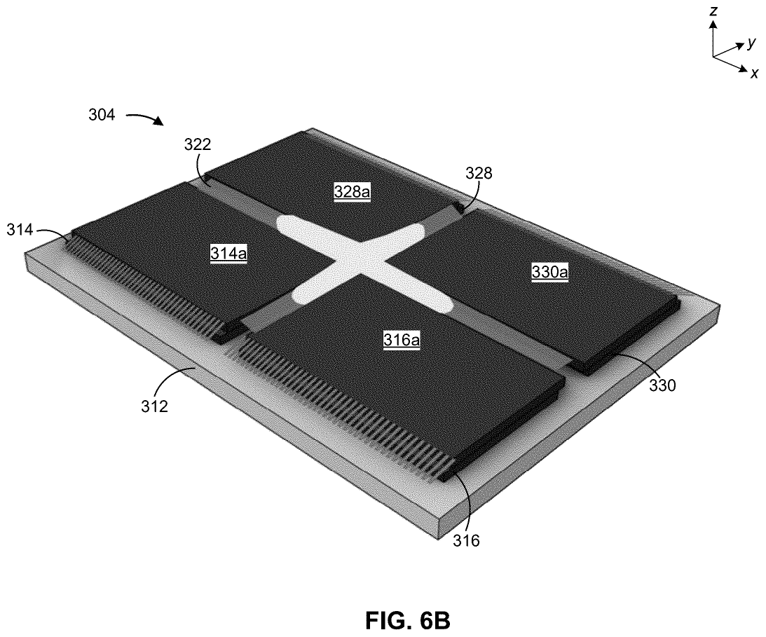

FIGS. 6A-6B are diagrams of an example of the semiconductor package 304. As shown in FIG. 6A, the thermally-conductive filler 322 may extend from the gap beyond the tops of the first semiconductor die stack 314a and the second semiconductor die stack 316a, as described herein. If die stacking is not used, the thermally-conductive filler 322 may extend beyond the tops of the first semiconductor die 314 and the second semiconductor die 316.

As shown in FIG. 6B, as an example, the thermally-conductive filler 322 may extend from the gap at a central region of the gap. For example, a first portion of the thermally-conductive filler 322 may extend from the gap beyond the tops of the first semiconductor die stack 314a and the second semiconductor die stack 316a (or the tops of the first semiconductor die 314 and the second semiconductor die 316 if die stacking is not used), and a second portion of the thermally-conductive filler 322 may be filled in the gap up to a level that is short of, or flush to, the tops of the first semiconductor die stack 314a and the second semiconductor die stack 316a (or the tops of the first semiconductor die 314 and the second semiconductor die 316 if die stacking is not used). As shown, the first portion may be cross-shaped (e.g., when the gap is cross-shaped, as described herein). Alternatively, the first portion may be linear.

As indicated above, FIGS. 6A-6B are provided as an example. Other examples may differ from what is described with respect to FIGS. 6A-6B.

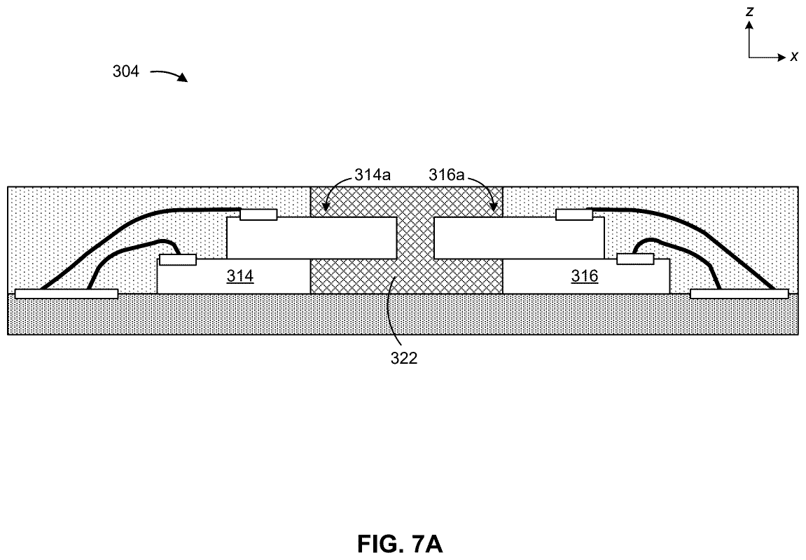

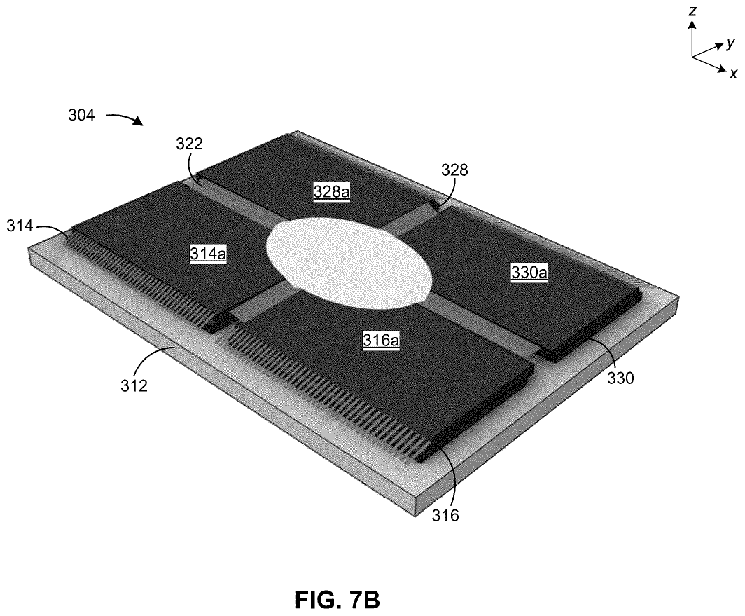

FIGS. 7A-7B are diagrams of an example of the semiconductor package 304. As shown in FIG. 7A, the thermally-conductive filler 322 may extend from the gap onto top surfaces of the first semiconductor die stack 314a and the second semiconductor die stack 316a, as described herein. If die stacking is not used, the thermally-conductive filler 322 may extend from the gap onto top surfaces of the first semiconductor die 314 and the second semiconductor die 316.

As shown in FIG. 7B, as an example, the thermally-conductive filler 322 may extend from the gap at a central region of the gap. For example, a first portion of the thermally-conductive filler 322 may extend from the gap onto the tops of the first semiconductor die stack 314a and the second semiconductor die stack 316a (or the tops of the first semiconductor die 314 and the second semiconductor die 316 if die stacking is not used), and a second portion of the thermally-conductive filler 322 may be filled in the gap up to a level that is short of, or flush to, the tops of the first semiconductor die stack 314a and the second semiconductor die stack 316a (or the tops of the first semiconductor die 314 and the second semiconductor die 316 if die stacking is not used). The first portion may have a circular shape, as shown, or another shape.

As indicated above, FIGS. 7A-7B are provided as an example. Other examples may differ from what is described with respect to FIGS. 7A-7B.

Each of the illustrated x-axis, y-axis, and z-axis is substantially perpendicular to the other two axes. In other words, the x-axis is substantially perpendicular to the y-axis and the z-axis, the y-axis is substantially perpendicular to the x-axis and the z-axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

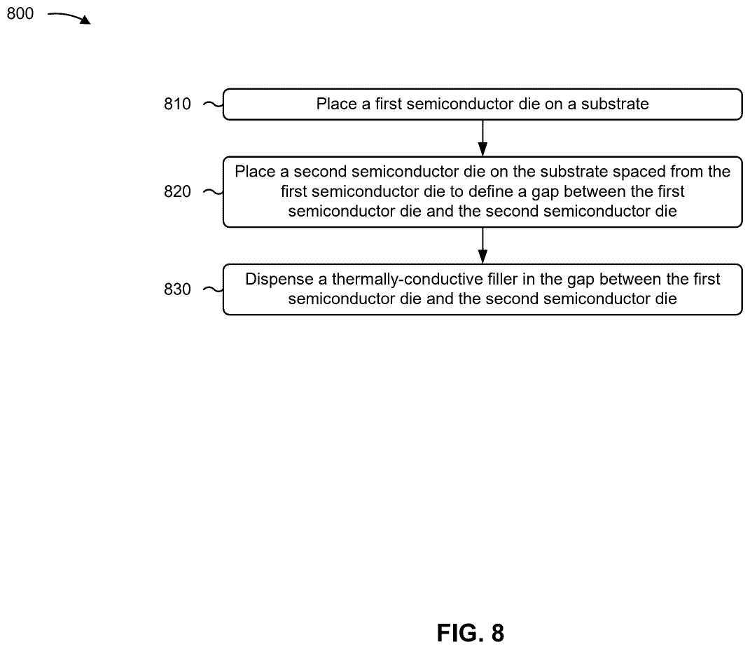

FIG. 8 is a flowchart of an example method 800 of forming an integrated assembly or memory device having a thermally-conductive filler in an inter-die gap. In some implementations, one or more process blocks of FIG. 8 may be performed by various semiconductor manufacturing equipment.

As shown in FIG. 8, the method 800 may include placing a first semiconductor die on a substrate (block 810). As further shown in FIG. 8, the method 800 may include placing a second semiconductor die on the substrate spaced from the first semiconductor die to define a gap between the first semiconductor die and the second semiconductor die (block 820). As further shown in FIG. 8, the method 800 may include dispensing a thermally-conductive filler in the gap between the first semiconductor die and the second semiconductor die (block 830).

The method 800 may include additional aspects, such as any single aspect or any combination of aspects described below and/or in connection with one or more other methods described elsewhere herein.

In a first aspect, the method 800 includes forming a first dam in the gap and a second dam in the gap, and dispensing the thermally-conductive filler includes dispensing the thermally-conductive filler between the first dam and the second dam.

In a second aspect, alone or in combination with the first aspect, dispensing the thermally-conductive filler includes spiral dispensing the thermally-conductive filler on the first semiconductor die and the second semiconductor die to cause the thermally-conductive filler to flow into the gap.

In a third aspect, alone or in combination with one or more of the first and second aspects, the method 800 includes forming a casing over the first semiconductor die and the second semiconductor die, where the thermally-conductive filler has a higher thermal conductivity than a thermal conductivity of the casing.

In a fourth aspect, alone or in combination with one or more of the first through third aspects, placing the first semiconductor die on the substrate includes placing a first semiconductor die stack, that includes the first semiconductor die, on the substrate, placing the second semiconductor die on the substrate includes placing a second semiconductor die stack, that includes the second semiconductor die, on the substrate, and the gap is between the first semiconductor die stack and the second semiconductor die stack.

In a fifth aspect, alone or in combination with one or more of the first through fourth aspects, the method 800 includes curing the thermally-conductive filler.

Although FIG. 8 shows example blocks of the method 800, in some implementations, the method 800 may include additional blocks, fewer blocks, different blocks, or differently arranged blocks than those depicted in FIG. 8. In some implementations, the method 800 may include forming the structure 304, an integrated assembly that includes the structure 304, any part described herein of the structure 304, and/or any part described herein of an integrated assembly that includes the structure 304. For example, the method 800 may include forming one or more of the parts 312-322 and/or 328-330.

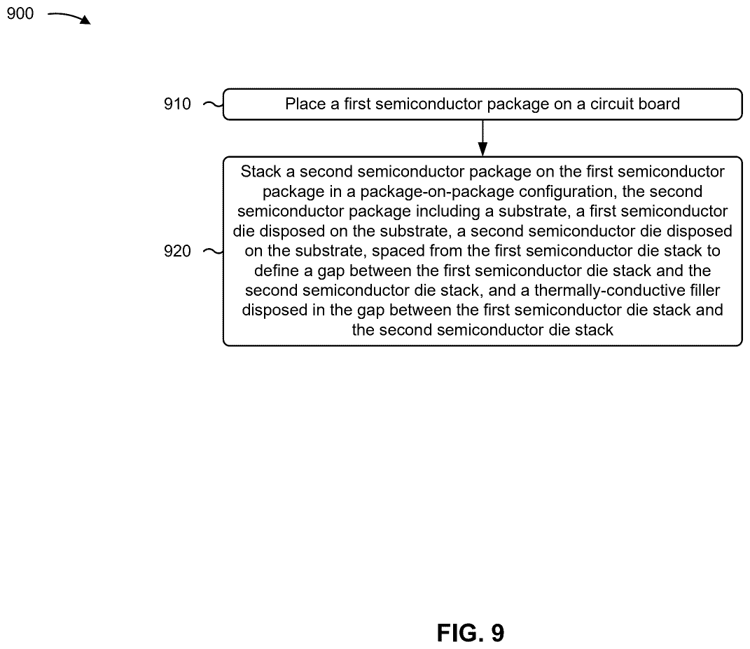

FIG. 9 is a flowchart of an example method 900 of forming an integrated assembly or memory device having a thermally-conductive filler in an inter-die gap. In some implementations, one or more process blocks of FIG. 9 may be performed by various semiconductor manufacturing equipment.

As shown in FIG. 9, the method 900 may include placing a first semiconductor package on a circuit board (block 910). As further shown in FIG. 9, the method 900 may include stacking a second semiconductor package on the first semiconductor package in a package-on-package configuration, the second semiconductor package include a substrate, a first semiconductor die disposed on the substrate, a second semiconductor die disposed on the substrate, spaced from the first semiconductor die stack to define a gap between the first semiconductor die stack and the second semiconductor die stack, and a thermally-conductive filler disposed in the gap between the first semiconductor die stack and the second semiconductor die stack (block 920).

The method 900 may include additional aspects, such as any single aspect or any combination of aspects described below and/or in connection with one or more other methods described elsewhere herein.

In a first aspect, the method 900 includes placing a heat spreader on the second semiconductor package.

In a second aspect, alone or in combination with the first aspect, the method 900 includes forming a first redistribution layer between the circuit board and the first semiconductor package, and forming a second redistribution layer between the first semiconductor package and the second semiconductor package.

Although FIG. 9 shows example blocks of the method 900, in some implementations, the method 900 may include additional blocks, fewer blocks, different blocks, or differently arranged blocks than those depicted in FIG. 9. In some implementations, the method 900 may include forming the structure 300, an integrated assembly that includes the structure 300, any part described herein of the structure 300, and/or any part described herein of an integrated assembly that includes the structure 300. For example, the method 900 may include forming one or more of the parts 302-330.

In some implementations, a semiconductor device assembly includes a substrate; a first semiconductor die disposed on the substrate; a second semiconductor die disposed on the substrate, spaced from the first semiconductor die to define a gap between the first semiconductor die and the second semiconductor die; and a thermally-conductive filler disposed in the gap between the first semiconductor die and the second semiconductor die.

In some implementations, an apparatus includes a first semiconductor package; and a second semiconductor package in a package-on-package configuration with the first semiconductor package, the second semiconductor package includes: a substrate; a first semiconductor die stack disposed on the substrate; a second semiconductor die stack disposed on the substrate, spaced from the first semiconductor die stack to define a gap between the first semiconductor die stack and the second semiconductor die stack; and a thermally-conductive filler disposed in the gap between the first semiconductor die stack and the second semiconductor die stack.

In some implementations, a method includes placing a first semiconductor die on a substrate; placing a second semiconductor die on the substrate spaced from the first semiconductor die to define a gap between the first semiconductor die and the second semiconductor die; and dispensing a thermally-conductive filler in the gap between the first semiconductor die and the second semiconductor die.

In some implementations, a method includes placing a first semiconductor package on a circuit board; and stacking a second semiconductor package on the first semiconductor package in a package-on-package configuration, the second semiconductor package including a substrate, a first semiconductor die disposed on the substrate, a second semiconductor die disposed on the substrate, spaced from the first semiconductor die stack to define a gap between the first semiconductor die stack and the second semiconductor die stack, and a thermally-conductive filler disposed in the gap between the first semiconductor die stack and the second semiconductor die stack.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.”

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A semiconductor device assembly, comprising:
a substrate;
a first semiconductor die disposed on the substrate;
a second semiconductor die disposed on the substrate, spaced from the first semiconductor die to define a gap between the first semiconductor die and the second semiconductor die; and
a thermally-conductive filler disposed in the gap between the first semiconductor die and the second semiconductor die.

2. The semiconductor device assembly of claim 1, further comprising a casing encapsulating the first semiconductor die and the second semiconductor die,
wherein the thermally-conductive filler has a higher thermal conductivity than a thermal conductivity of the casing.

3. The semiconductor device assembly of claim 1, wherein the thermally-conductive filler has a thermal conductivity of at least 10 watts per meter-kelvin.

4. The semiconductor device assembly of claim 1, wherein the first semiconductor die is included in a first semiconductor die stack and the second semiconductor die is included in a second semiconductor die stack, and
wherein the gap is defined between the first semiconductor die stack and the second semiconductor die stack.

5. The semiconductor device assembly of claim 4, wherein top-most elements of the first semiconductor die stack and the second semiconductor die stack are dummy dies or spacers.

6. The semiconductor device assembly of claim 4, wherein the thermally-conductive filler extends from the gap beyond tops of the first semiconductor die stack and the second semiconductor die stack.

7. The semiconductor device assembly of claim 4, wherein the thermally-conductive filler extends from the gap onto top surfaces of the first semiconductor die stack and the second semiconductor die stack.

8. The semiconductor device assembly of claim 1, further comprising:
a first dam disposed in the gap and a second dam disposed in the gap,
wherein the thermally-conductive filler is disposed in the gap between the first dam and the second dam.

9. An apparatus, comprising:
a first semiconductor package; and
a second semiconductor package in a package-on-package configuration with the first semiconductor package, the second semiconductor package comprising:
a substrate;
a first semiconductor die stack disposed on the substrate;
a second semiconductor die stack disposed on the substrate, spaced from the first semiconductor die stack to define a gap between the first semiconductor die stack and the second semiconductor die stack; and
a thermally-conductive filler disposed in the gap between the first semiconductor die stack and the second semiconductor die stack.

10. The apparatus of claim 9, wherein the first semiconductor package is a system on a chip (SoC), and
wherein the second semiconductor package is a memory package.

11. The apparatus of claim 9, further comprising:
a heat spreader disposed on the second semiconductor package.

12. The apparatus of claim 9, wherein the thermally-conductive filler extends from the gap beyond tops of the first semiconductor die stack and the second semiconductor die stack.

13. The apparatus of claim 9, wherein the thermally-conductive filler extends from the gap onto top surfaces of the first semiconductor die stack and the second semiconductor die stack.

14. The apparatus of claim 9, wherein the second semiconductor package further comprises a third semiconductor die stack and a fourth semiconductor die stack disposed on the substrate,
wherein the gap is a cross-shaped gap defined between the first semiconductor die stack, the second semiconductor die stack, the third semiconductor die stack, and the fourth semiconductor die stack.

15. The apparatus of claim 9, wherein the thermally-conductive filler is a thermally-conductive paste.

16. A method, comprising:
placing a first semiconductor die on a substrate;
placing a second semiconductor die on the substrate spaced from the first semiconductor die to define a gap between the first semiconductor die and the second semiconductor die; and
dispensing a thermally-conductive filler in the gap between the first semiconductor die and the second semiconductor die.

17. The method of claim 16, further comprising:
forming a first dam in the gap and a second dam in the gap,
wherein dispensing the thermally-conductive filler comprises:
dispensing the thermally-conductive filler between the first dam and the second dam.

18. The method of claim 16, wherein dispensing the thermally-conductive filler comprises:
spiral dispensing the thermally-conductive filler on the first semiconductor die and the second semiconductor die to cause the thermally-conductive filler to flow into the gap.

19. The method of claim 16, further comprising:
forming a casing over the first semiconductor die and the second semiconductor die,
wherein the thermally-conductive filler has a higher thermal conductivity than a thermal conductivity of the casing.

20. The method of claim 16, wherein placing the first semiconductor die on the substrate comprises placing a first semiconductor die stack, that includes the first semiconductor die, on the substrate,
wherein placing the second semiconductor die on the substrate comprises placing a second semiconductor die stack, that includes the second semiconductor die, on the substrate, and
wherein the gap is between the first semiconductor die stack and the second semiconductor die stack.
